(19) United States
(12) Patent Application Publication
(10) Pub. No.: US 2009/0046422 A1
(43) Pub. Date: Feb. 19, 2009

(54) Protection structure for heat dispersing device of power supplier

(75) Inventor: Shao-Feng Lu, Taoyuan Hsien (TW)

Correspondence Address: Joe McKinney Muncy, PO Box 1364, Fairfax, VA, 22038-1364, US

(73) Assignees: FSP TECHNOLOGY INC.; 3Y POWER TECHNOLOGY (TAIWAN) INC.

(21) Appl. No.: 11/889,595

(22) Filed: Aug. 15, 2007

(51) Int. Cl. H05K 7/20; H05K 5/00

(52) U.S. Cl. 361/690; 361/679; 361/752

(57) ABSTRACT

The present invention includes a metal housing, a power input end, a power output end, and an accommodating space thereinside between the power input end and the power output end, the accommodating space has a power processing unit mounted inside and the output terminal of the power processing unit is located at the power output end of the power supplier. The metal housing of the power supplier has an assembling opening mounted thereon and located above the accommodating space for assembling at least a heat dispersing device. The protection structure includes a fixing frame, mounted in the accommodating space and fixedly connected with two sides of the heat dispersing device and the metal housing, and a metal protection case, covered on the assembling opening and tightly engaged with the metal housing, wherein the metal protection case and the fixing frame respectively have positioning portions corresponding to each other.

### FIELD OF THE INVENTION

The present invention is related to a protection structure for a heat dispersing device, and more particularly, a protection structure for a heat dispersing device which can prevent air leakage and electromagnetic wave leakage from a power supplier.

### BACKGROUND OF THE INVENTION

Cases for industrial computer, according to the height thereof, can be divided into different standards, 1U, 2U, 3U and 4U, wherein the case of standard 1U is limited to be 40 mm height with a case thickness of 1 mm, so that the fan installed inside the case must be limited to have a height less than 38 mm. However, owing to the high operation efficiency of current electronic elements (which represents of high thermal energy), the fan with the height less than 38 mm can not sufficiently disperse the heat, so that the heat energy will accumulate inside the case. Therefore, a heat dispersing structure for the power supplier is developed, as disclosed in R.O.C. Patent Publication No. 490202. In this heat dispersing structure of power supplier, a 40 mm fan is mounted on a breakout opening at the front end of the standard 1U case, so that not only the heat generated by the data access device and the circuit board inside the metal case can be dispersed, but the fan which is assembled to the power supplier through the opening also conforms to the 1U standard.

However, since the above described fan for the power supplier is assembled with the metal case through the breakout opening, an air leakage might occur at the gap between the opening and the fan, and the electromagnetic wave might also leak out through the gap so as to cause an electromagnetic interference. Further, the power cord of the fan is exposed to the outside owing to the breakout opening, so that the wiring is easily damaged thereby causing electricity leakage or short circuit. Therefore, how to improve the heat dispersing structure for power supplier has already become a significant issue.

### SUMMARY OF THE INVENTION

The object of the present invention is to inhibit the electromagnetic interference, to entirely control the direction of air flow and protect the wiring of the heat dispersing device.

For achieving the object described above, a protection structure for a heat dispersing device of a power supplier is provided. The power supplier includes a metal housing, a power input end, a power output end, and an accommodating space thereinside between the power input end and the power output end, the accommodating space has a power processing unit mounted inside and the output terminal of the power processing unit is located at the power output end of the power supplier. The metal housing of the power supplier has an assembling opening mounted thereon and located above the accommodating space for assembling at least a heat dispersing device. The protection structure includes a fixing frame, mounted in the accommodating space and fixedly connected with two sides of the heat dispersing device and the metal housing, and a metal protection case, covered on the assembling opening and tightly engaged with the metal housing, wherein the metal protection case and the fixing frame respectively have positioning portions corresponding to each other, so as to be assembled by a position-limiting element.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1A is a schematic view showing three-dimensional appearance of the present invention in a preferred embodiment;

FIG. 1B is another schematic view showing three-dimensional appearance of the present invention in a preferred embodiment;

FIG. 2 is a schematic view showing decomposition of the present invention in a preferred embodiment;

FIG. 3 is a schematic view showing the arrangement of power cords in a preferred embodiment according to the present invention;

FIG. 4 is a schematic view showing a locking relationship in a preferred embodiment according to the present invention; and

FIG. 5 is a sectional view showing a preferred embodiment of the present invention.

### DESCRIPTION OF THE PREFERRED EMBODIMENT

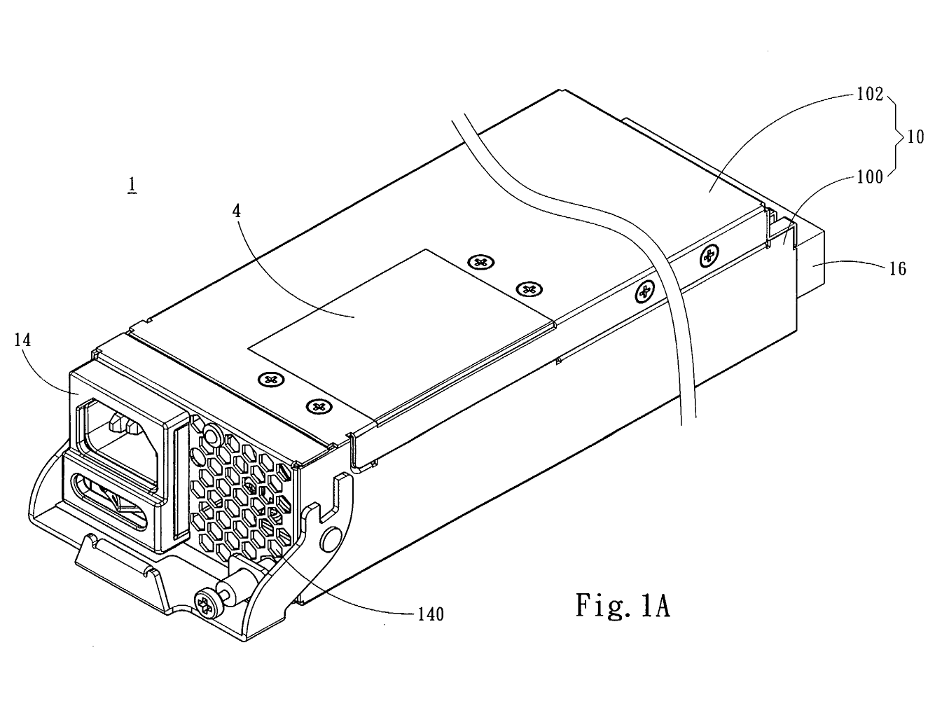

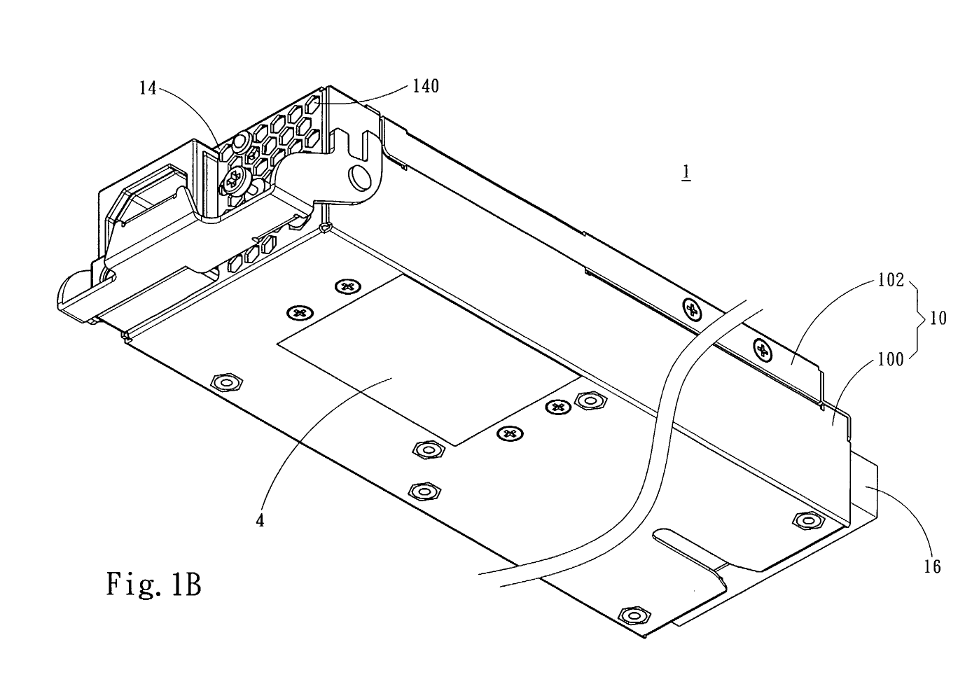

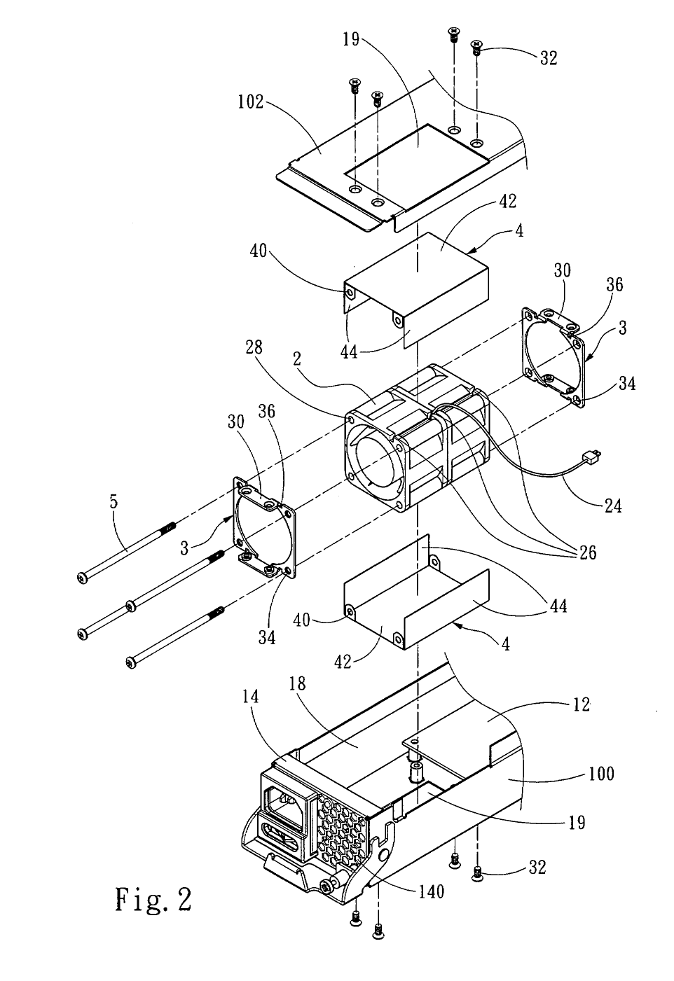

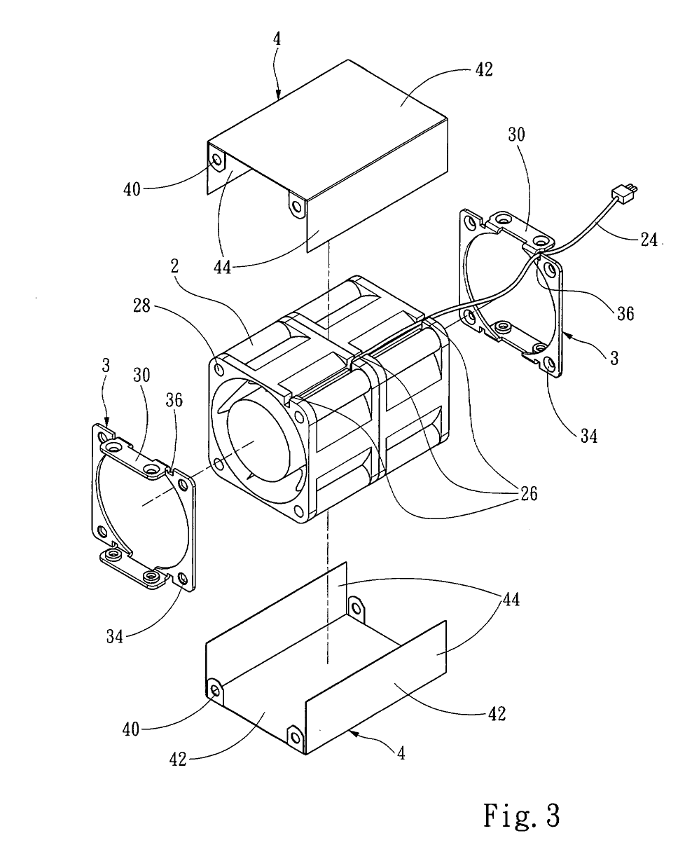

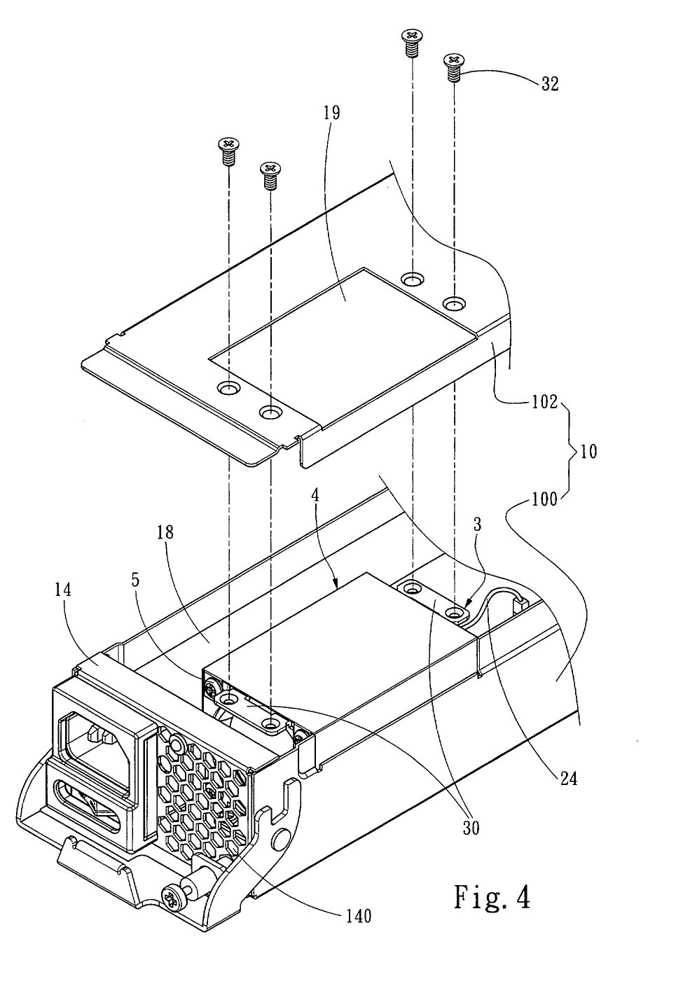

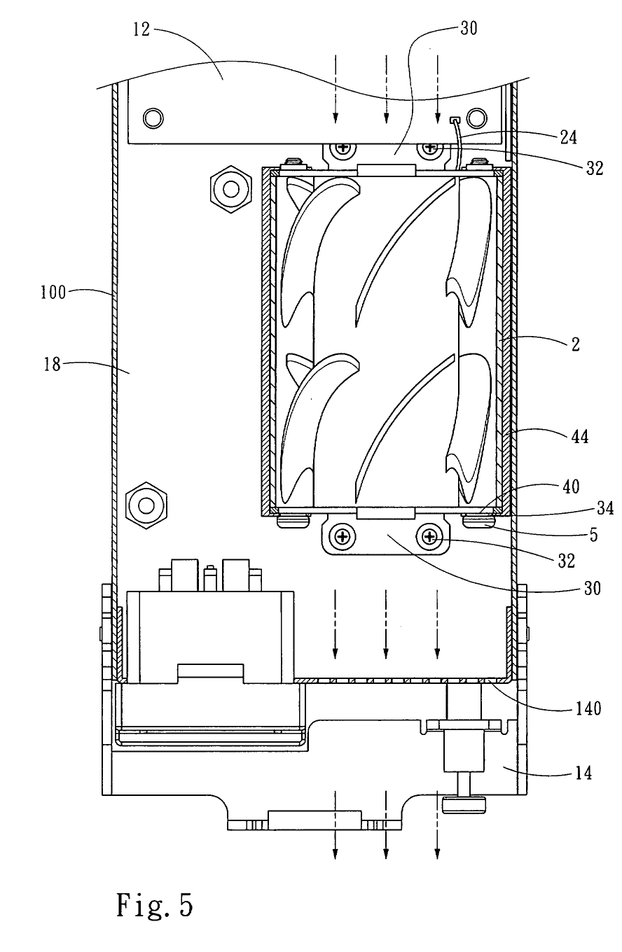

Please refer to FIG. 1A to FIG. 5, which are respectively a three-dimensional view, another three-dimensional view, a decomposition drawing, a schematic view showing the wiring arrangement, a schematic view showing the locking relationship and a sectional view of a preferred embodiment according to the present invention. As shown, the present invention provides a protection structure for a heat dispersing device of a power supplier. The power supplier 1 includes a metal housing 10, which includes a base 100 and a cover 102 covered on the base 100, a power input end 14 with plural vent holes 140, a power output end 16 and an accommodating space 18 inside the power supplier 1 between the power input end 14 and the power output end 16. The accommodating space 18 has a power processing unit 12 (such as, data access device, or circuit board) mounted therein, and the output terminal of the power processing unit 12 is located at the power output end 16 of the power supplier 1. Besides, the metal housing 10 of the power supplier 1 also has an assembling opening 19 mounted thereon and located above the accommodating space 18 for assembling at least a heat dispersing device 2. In this embodiment, the heat dispersing device 2 has a wiring arranging groove 26 mounted thereon for accommodating the power cord 24. The protection structure includes:

a fixing frame 3, mounted in the accommodating space 18 and fixedly connected with two sides of the heat dispersing device 2 and the metal housing 10, in which the fixing frame 3 is extended to have a corresponding pair of ears 30, so that through a cooperation between the ears 30 and the metal housing 10, screws 32 can be penetrated and locked, wherein the ears 30 further has a wiring exit 36 corresponding to the wiring arranging groove 26 for penetrating out the power cord 24 to connect to the power processing unit 12; and

a metal protection case 4, covered on the assembling opening 19 and tightly engaged with the metal housing 10, wherein the metal protection case 4 and the fixing frame 3 respectively have a first positioning portion 34 and a second positioning portion 40 corresponding to each other, so as to be assembled by a position-limiting element 5, and wherein the metal protection case 4 has a plane 42 and flanks 44 mounted at two sides of the surface 42, so that the plane 42 can smoothly cover the heat dispersing device 2 to prevent the power cord 24 of the heat dispersing device 2 from being damaged or cut, and through the plane 42 and flanks 44, the heat dispersing device 2 can be completely sealed for avoiding the electromagnetic wave inside the power supplier 1 from leakage.

Besides, the heat dispersing device 2 also has a third positioning portion 28 for being assembled by the position-limiting element 5, so that the position-limiting element 5 can penetrate through the first, the second and the third positioning portions 34, 40 28, thereby tightly assembling the fixing frame 3, the metal protection case 4 and the heat dispersing device 2 together.

It should be noticed that, in this embodiment, between the power input end 14 and the heat dispersing device 2, an air channel (not shown) is formed, and through the vent holes 140, the air can flow to the outside for heat dispersing. Here, the air channel can provide a more concentrated air flow for increasing the heat dispersing effect through utilizing a hollow tube element (not shown).

In the aforesaid, the present invention utilizes a plane 42 to cover the heat dispersing device 2 for preventing the power cord 24 of the heat dispersing device 2 from being damaged or cut, and through the plane 42 and flanks 44, the heat dispersing device 2 can be completely sealed and the metal protection case 4 and the metal housing 10 can be tightly engaged, so as to avoid the electromagnetic wave inside the power supplier 1 from leakage, and thus, inhibit the electromagnetic interference and totally control the air flow direction. Therefore, the present invention not only can prevent the air leakage and electromagnetic interference in the prior art, but also can avoid the power cord of the heat dispersing device from being exposed to the outside.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A protection structure for a heat dispersing device of a power supplier, which comprises a metal housing, a power input end, a power output end, and an accommodating space thereinside between the power input end and the power output end, wherein the accommodating space has a power processing unit mounted inside and the output terminal of the power processing unit is located at the power output end of the power supplier, and the metal housing of the power supplier has an assembling opening mounted thereon and located above the accommodating space for assembling at least a heat dispersing device, the protection structure comprising:
a fixing frame, mounted in the accommodating space and fixedly connected with two sides of the heat dispersing device and the metal housing; and
a metal protection case, covered on the assembling opening and tightly engaged with the metal housing, wherein the metal protection case and the fixing frame respectively have positioning portions corresponding to each other, so as to be assembled by a position-limiting element.

2. The protection structure as claimed in claim 1, wherein the fixing frame is extended to have a pair of ears corresponding to the metal housing.

3. The protection structure as claimed in claim 1, wherein the metal protection case has a plane.

4. The protection structure as claimed in claim 3, wherein two sides of the plane respectively have a flank.

5. The protection structure as claimed in claim 1, wherein the heat dispersing device has a positioning portion for being assembled by the position-limiting element.

6. The protection structure as claimed in claim 1, wherein an air channel is formed between the power input end and the heat dispersing device.

7. The protection structure as claimed in claim 6, wherein the air channel is formed in a hollow tube element.

8. The protection structure as claimed in claim 1, wherein the power processing unit is a data access device.

9. The protection structure as claimed in claim 1, wherein the power processing unit is a circuit board.

10. The protection structure as claimed in claim 1, wherein the power processing unit comprises a data access device and a circuit board.
